(19) United States
(12) Patent Application Publication
(10) Pub. No.: US 2025/0366143 A1
(43) Pub. Date: Nov. 27, 2025

(54) SEMICONDUCTOR DEVICE

(71) Applicant: Mitsubishi Electric Corporation, Tokyo (JP)

(72) Inventors: Kazuya KONISHI, Tokyo (JP); Koji TANAKA, Tokyo (JP); Reona FURUKAWA, Tokyo (JP); Shinya SONEDA, Tokyo (JP); Tetsuya HIGASHI, Tokyo (JP)

(73) Assignee: Mitsubishi Electric Corporation, Tokyo (JP)

(21) Appl. No.: 19/061,448

(22) Filed: Feb. 24, 2025

(30) Foreign Application Priority Data
May 27, 2024 (JP) 2024-085445

(51) Int. Cl. H10D 64/27; H10D 12/00; H10D 64/00

(52) U.S. Cl. CPC H10D 64/516; H10D 12/481; H10D 64/117; H10D 64/513; H10D 64/518

(57) ABSTRACT

A semiconductor device according to the present disclosure includes a dummy active trench including an upper electrode and a lower electrode. The upper electrode is connected to the gate electrode or to the emitter electrode, or at a floating potential. The lower electrode is connected to the gate electrode or to the emitter electrode, or at a floating potential. The dummy active trench includes an upper insulating film formed on a side surface of the upper electrode, a lower insulating film formed on a side surface of the lower electrode, and a boundary insulating film formed between the upper electrode and the lower electrode. The thickness of the upper insulating film in a right-left direction is larger than the thickness of the lower insulating film in the right-left direction. In a sectional view, the area of the upper electrode is smaller than the area of the lower electrode.

### BACKGROUND

### Technical Field

The present disclosure relates to a semiconductor device to be controlled in conduction by a gate signal.

### Description of the Background Art

An insulated gate bipolar transistor (IGBT) is required to achieve both reduction in recovery dv/dt having correlation with noise and reduction in turn-on loss, and these are realized effectively by increasing Cgc/Cge showing a gate capacitance ratio. Here, Cgc is a capacitance between a gate electrode and a collector electrode, and Cge is a capacitance between the gate electrode and an emitter electrode.

In a semiconductor device conventionally known, increasing Cgc/Cge is encouraged by providing a two-part dummy active trench structure (see Japanese Patent Application Laid-Open No. 2022-78755, for example).

According to Japanese Patent Application Laid-Open No. 2022-78755, breakdown of a boundary insulating film formed between an upper dummy part and a lower active part of the two-part dummy active trench may be caused by a potential difference generated between the upper dummy part and the lower active part, and this causes a problem with the reliability of the insulating film. The reliability of the insulating film might be improved by increasing the thickness of a lower insulating film formed on a side surface of the lower active part. However, increasing the thickness of the lower insulating film increases stress applied on a cell part to result in large chip warpage. Thus, a problem to be solved is to achieve both improvement of the reliability of the insulating film and suppression of chip warpage.

### SUMMARY

The present disclosure is intended to provide a semiconductor device capable of achieving both improvement of the reliability of an insulating film and suppression of chip warpage.

A semiconductor device according to the present disclosure includes: a semiconductor substrate; an emitter electrode formed on the semiconductor substrate; a gate electrode formed on the semiconductor substrate; a drift layer of a first conductivity type formed in the semiconductor substrate; a source layer of the first conductivity type formed in an upper surface side of the semiconductor substrate; a base layer of a second conductivity type formed in the upper surface side of the semiconductor substrate; a collector electrode formed under the semiconductor substrate; and a dummy active trench including an upper electrode and a lower electrode provided in an upper part and a lower part respectively in a trench of the semiconductor substrate. The upper electrode is connected to the gate electrode or to the emitter electrode, or at a floating potential. The lower electrode is connected to the gate electrode or to the emitter electrode, or at a floating potential. The dummy active trench includes an upper insulating film formed on a side surface of the upper electrode, a lower insulating film formed on a side surface of the lower electrode, and a boundary insulating film formed between the upper electrode and the lower electrode. The thickness of the upper insulating film in a right-left direction is larger than the thickness of the lower insulating film in the right-left direction. In a sectional view, the area of the upper electrode is smaller than the area of the lower electrode.

According to the present disclosure, it is possible to achieve both improvement of the reliability of an insulating film and suppression of chip warpage.

These and other objects, features, aspects and advantages of the present invention will become more apparent from the following detailed description of the present disclosure when taken in conjunction with the accompanying drawings.

### BRIEF DESCRIPTION OF THE DRAWINGS

FIG. 1 is a sectional view of a semiconductor device according to a first preferred embodiment;

FIG. 2 is a sectional view of a semiconductor device according to a first modification of the first preferred embodiment;

FIG. 3 is a sectional view of a semiconductor device according to a second modification of the first preferred embodiment;

FIG. 4 is a sectional view of a semiconductor device according to a fourth modification of the first preferred embodiment;

FIG. 5 is a sectional view of a semiconductor device according to a seventh modification of the first preferred embodiment;

FIG. 6 is a sectional view of a semiconductor device according to an eighth modification of the first preferred embodiment;

FIG. 7 is a sectional view of a semiconductor device according to a ninth modification of the first preferred embodiment;

FIG. 8 is a sectional view of a semiconductor device according to a tenth modification of the first preferred embodiment;

FIG. 9 is a sectional view of a semiconductor device according to a twelfth modification of the first preferred embodiment;

FIG. 10 is a sectional view of a semiconductor device according to a thirteenth modification of the first preferred embodiment;

FIG. 11 is a sectional view of a semiconductor device according to a fourteenth modification of the first preferred embodiment;

FIG. 12 is a plan view of the semiconductor device according to the fourteenth modification of the first preferred embodiment;

FIG. 13 is a sectional view of a semiconductor device according to a fifteenth modification of the first preferred embodiment;

FIG. 14 is a sectional view of a semiconductor device according to a sixteenth modification of the first preferred embodiment;

FIG. 15 is a sectional view of a semiconductor device according to a seventeenth modification of the first preferred embodiment;

FIG. 16 is a sectional view of a semiconductor device according to a second preferred embodiment;

FIG. 17 is a sectional view of a semiconductor device according to a first modification of the second preferred embodiment;

FIG. 18 is a sectional view of a semiconductor device according to a second modification of the second preferred embodiment;

FIG. 19 is a sectional view of a semiconductor device according to a third modification of the second preferred embodiment;

FIG. 20 is a sectional view of a semiconductor device according to a fourth modification of the second preferred embodiment;

FIG. 21 is a sectional view of a semiconductor device according to a fifth modification of the second preferred embodiment;

FIG. 22 is a plan view of a semiconductor device according to a sixth modification of the second preferred embodiment;

FIG. 23 is a sectional view of the semiconductor device according to the sixth modification of the second preferred embodiment taken along Y1-Y2;

FIG. 24 is a plan view of a semiconductor device according to a seventh modification of the second preferred embodiment;

FIG. 25 is a sectional view of the semiconductor device according to the seventh modification of the second preferred embodiment taken along Y3-Y4;

FIG. 26 is a sectional view of a semiconductor device according to an eighth modification of the second preferred embodiment; and

FIG. 27 is a sectional view of a semiconductor device according to a different example of a ninth modification of the second preferred embodiment.

### DESCRIPTION OF THE PREFERRED EMBODIMENTS

Semiconductor devices according to preferred embodiments will be described below by referring to the drawings. The same or corresponding constituting elements will be given the same signs, and repeated descriptions thereof may be omitted. In the following description, n and p denote conductivity types of semiconductor. In the present disclosure, description will be given with a first conductivity type denoted as the n-type and a second conductivity type as the-p type. These conductivity types may be reversed.

### First Preferred Embodiment

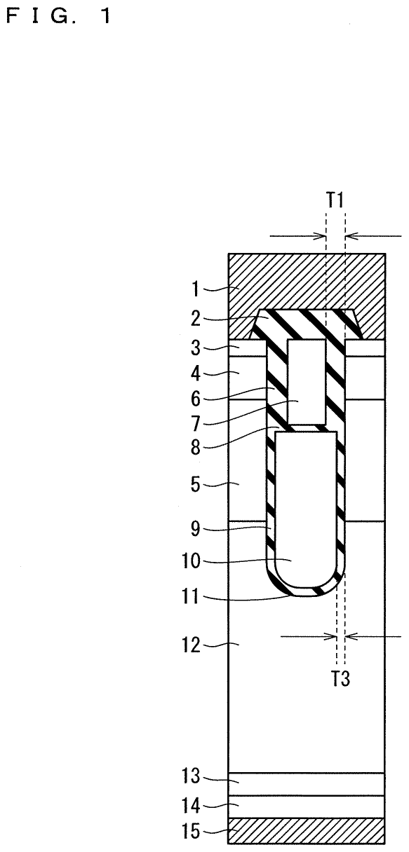

FIG. 1 is a sectional view of a semiconductor device according to a first preferred embodiment. In FIG. 1, a semiconductor substrate is in a range from a source layer 3 to a collector layer 14. In FIG. 1, an upper end of the source layer 3 in the plane of the drawing is called an upper surface of the semiconductor substrate, and a lower end of the collector layer 14 in the plane of the drawing is called a lower surface of the semiconductor substrate. The upper surface and the lower surface face each other.

As shown in FIG. 1, the semiconductor device includes an n-type drift layer 12 provided between the upper surface and the lower surface of the semiconductor substrate.

An n-type carrier accumulation layer 5 having a higher n-type impurity concentration than the drift layer 12 is provided on an upper surface side of the drift layer 12. The carrier accumulation layer 5 is provided between a base layer 4 and the drift layer 12. Providing the carrier accumulation layer 5 causes an electric field to concentrate on a lower end of the carrier accumulation layer 5. This allows an electric field intensity to be relaxed between an upper electrode 7 and a lower electrode 10, making it possible to improve the reliability of an insulating film. In the configuration of the semiconductor device, instead of providing the carrier accumulation layer 5, the drift layer 12 may be provided further in a region of the carrier accumulation layer 5 shown in FIG. 1.

The base layer 4 of the p-type is provided on an upper surface side of the carrier accumulation layer 5. The source layer 3 of the n-type is provided on an upper surface side of the base layer 4.

The semiconductor substrate is provided with a dummy active trench 11. The dummy active trench 11 includes the upper electrode 7 and the lower electrode 10 provided in an upper part and a lower part respectively in a trench of the semiconductor substrate. The upper electrode 7 is connected to a gate electrode (not shown in the drawings) or to an emitter electrode 1, or at a floating potential. The lower electrode 10 is connected to the gate electrode (not shown in the drawings) or to the emitter electrode 1, or at a floating potential. As an example, the upper electrode 7 is connected to a part other than the gate electrode, and the lower electrode 10 is connected to the gate electrode. The “trench” means a hole provided in the semiconductor substrate or a structure formed in the hole.

The dummy active trench 11 includes an upper insulating film 6 formed on a side surface of the upper electrode 7, a lower insulating film 9 formed on a side surface of the lower electrode 10, and a boundary insulating film 8 formed between the upper electrode 7 and the lower electrode 10. The upper electrode 7 and the lower electrode 10 are electrically separated from each other via the boundary insulating film 8. A thickness T1 of the upper insulating film 6 in a right-left direction is larger than a thickness T3 of the lower insulating film 9 in the right-left direction. The right-left direction mentioned herein is a direction (a width direction of the dummy active trench 11) perpendicular to a depth direction of the dummy active trench 11. In a sectional view, the area of the upper electrode 7 is smaller than the area of the lower electrode 10.

An interlayer insulating film 2 is provided on the dummy active trench 11. The emitter electrode 1 is provided over the source layer 3 and the interlayer insulating film 2.

An n-type buffer layer 13 having a higher n-type impurity concentration than the drift layer 12 is provided on a lower surface side of the drift layer 12. In the configuration of the semiconductor device, instead of providing the buffer layer 13, the drift layer 12 may be provided further in a region of the buffer layer 13 shown in FIG. 1. The collector layer 14 of the p-type is provided on a lower surface side of the buffer layer 13. A collector electrode 15 is provided on a lower surface side of the collector layer 14.

According to the first preferred embodiment, as a result of the small thickness T3 of the lower insulating film 9, it is possible to suppress chip warpage. Furthermore, as a result of the large thickness T1 of the upper insulating film 6, the area of the upper electrode 7 is reduced, making it possible to improve the reliability of the insulating film. Moreover, as the area of the upper electrode 7 facing the thick upper insulating film 6 subjected to large stress is smaller than the area of the lower electrode 10 facing the thin lower insulating film 9 subjected to small stress, stress is reduced as a whole, making it possible to suppress chip warpage. Specifically, according to the first preferred embodiment, it is possible to achieve both improvement of the reliability of the insulating film and suppression of chip warpage.

### <First Modification>

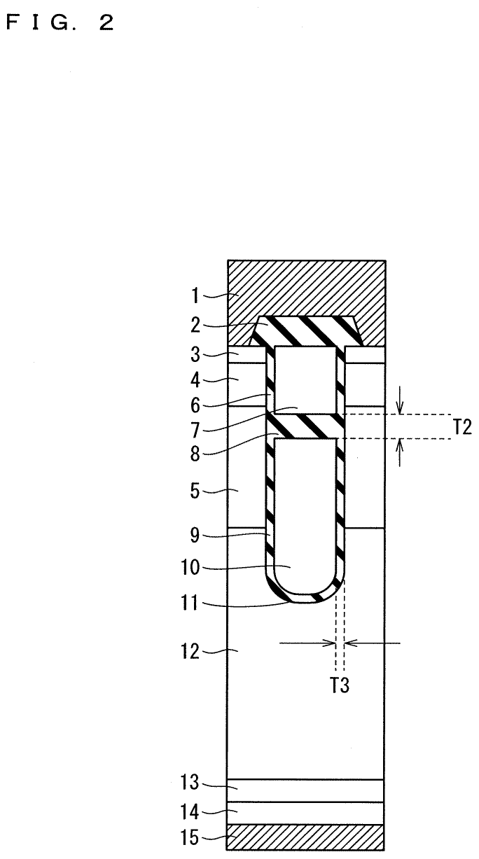

FIG. 2 is a sectional view of a semiconductor device according to a first modification of the first preferred embodiment. As shown in FIG. 2, in the semiconductor device according to the first modification, a thickness T2 of the boundary insulating film 8 in a top-bottom direction is larger than the thickness T3 of the lower insulating film 9 in the right-left direction. In a sectional view, the area of the upper electrode 7 is smaller than the area of the lower electrode 10. The top-bottom direction mentioned herein is the depth direction of the dummy active trench 11.

According to the first modification, as a result of the small thickness T3 of the lower insulating film 9 in the right-left direction, it is possible to suppress chip warpage. Furthermore, as a result of the large thickness T2 of the boundary insulating film 8 in the top-bottom direction, a distance between the upper electrode 7 and the lower electrode 10 is increased to allow improvement of the reliability of the insulating film.

### <Second Modification>

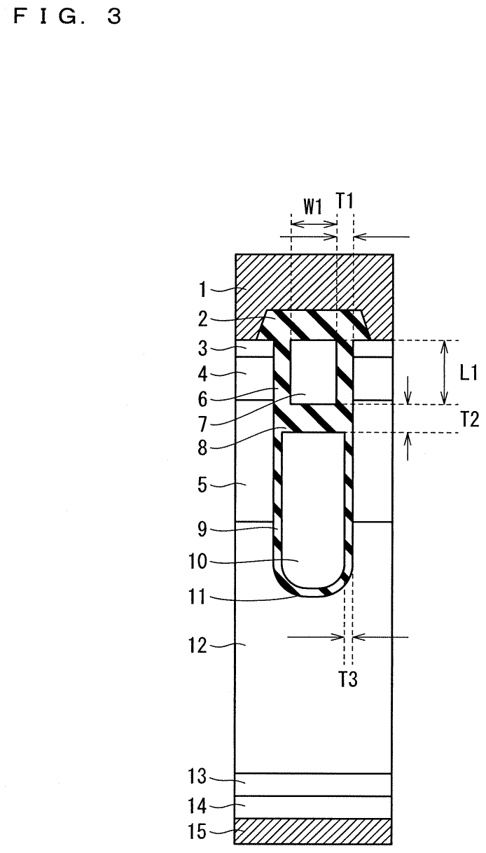

FIG. 3 is a sectional view of a semiconductor device according to a second modification of the first preferred embodiment. As shown in FIG. 3, the thickness T1 of the upper insulating film 6 in the right-left direction, the thickness T2 of the boundary insulating film 8 in the top-bottom direction, and the thickness T3 of the lower insulating film 9 in the right-left direction have a relationship as follows: the thickness T2 of the boundary insulating film 8 in the top-bottom direction>the thickness T1 of the upper insulating film 6 in the right-left direction>the thickness T3 of the lower insulating film 9 in the right-left direction. Namely, the thickness T2 of the boundary insulating film 8 in the top-bottom direction is the largest thickness, the thickness T1 of the upper insulating film 6 in the right-left direction is the next largest thickness, and the thickness T3 of the lower insulating film 9 in the right-left direction is the smallest thickness.

According to the second modification, as the thickness T2 of the boundary insulating film 8 in the top-bottom direction is larger than the thickness T1 of the upper insulating film 6 in the right-left direction, it is possible to reduce an aspect ratio of a length L1 of the upper electrode 7 in the top-bottom direction (the depth of the upper electrode 7) relative to a length W1 of the upper electrode 7 in the right-left direction (the width of the upper electrode 7) (L1/W1). Thus, it is possible to improve the embeddability of the upper electrode 7.

### <Third Modification>

Like in the semiconductor devices shown in FIGS. 1 and 3, the boundary insulating film 8 may be arranged above the center of the dummy active trench 11 in the top-bottom direction.

Employing this configuration makes the area of the upper electrode 7 facing the thick upper insulating film 6 subjected to large stress smaller than the area of the lower electrode 10 facing the thin lower insulating film 9 subjected to small stress. This reduces stress as a whole, making it possible to suppress chip warpage.

### <Fourth Modification>

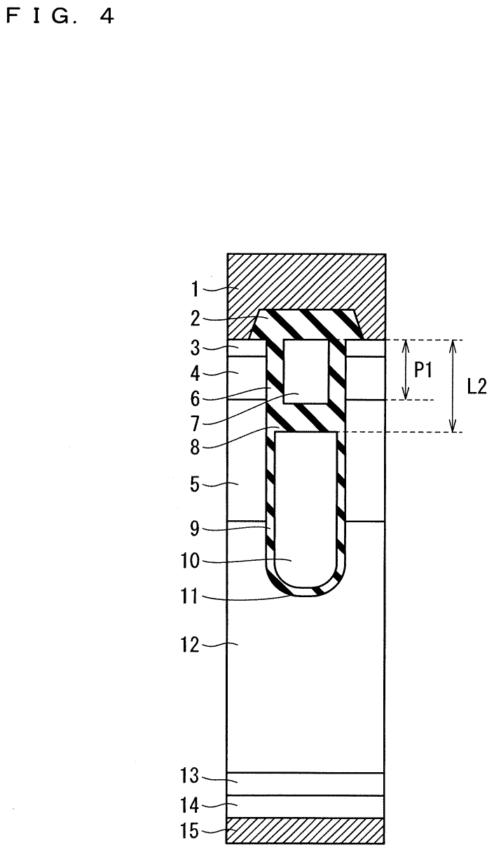

FIG. 4 is a sectional view of a semiconductor device according to a fourth modification of the first preferred embodiment. As shown in FIG. 4, a length L2 from the upper surface of the semiconductor substrate to an upper end of the lower electrode 10 is larger than a length P1 from the upper surface of the semiconductor substrate to a lower end of the base layer 4 in the top-bottom direction.

If the upper end of the lower electrode 10 juts out into the base layer 4, Cge is increased to reduce Cgc/Cge. According to the fourth modification, making the length L2 from the upper surface of the semiconductor substrate to the upper end of the lower electrode 10 larger than the length P1 of the base layer 4 in the top-bottom direction allows reduction in Cge, making it possible to achieve both reduction in recovery dv/dt and reduction in turn-on loss.

While the fourth modification is applied to the semiconductor device shown in FIG. 3 in the exemplary case described above, the fourth modification may be applied to the semiconductor device shown in FIG. 1 or 2.

### <Fifth Modification>

Like in the semiconductor devices shown in FIGS. 1 to 3, the boundary insulating film 8 may be arranged above the lower end of the carrier accumulation layer 5.

Employing this configuration allows the boundary insulating film 8 involved in the reliability of the insulating film to be separated from the lower end of the carrier accumulation layer 5 as a high electric field region, making it possible to improve the reliability of the insulating film.

### <Sixth Modification>

Like in the semiconductor devices shown in FIGS. 1 to 3, the boundary insulating film 8 may be arranged above the center of the carrier accumulation layer 5.

Employing this configuration allows the boundary insulating film 8 involved in the reliability of the insulating film to be separated further from the lower end of the carrier accumulation layer 5 as a high electric field region, making it possible to improve the reliability of the insulating film.

### <Seventh Modification>

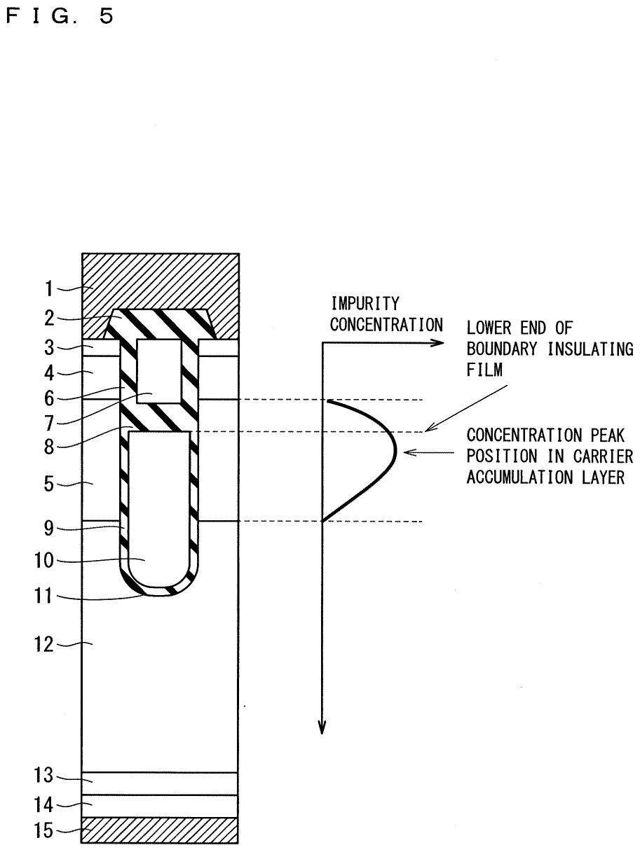

FIG. 5 is a sectional view of a semiconductor device according to a seventh modification of the first preferred embodiment. FIG. 5 shows a distribution of an impurity concentration in the carrier accumulation layer 5 in the semiconductor device shown in FIG. 3. As shown in FIG. 5, the boundary insulating film 8 may be arranged above a peak position of the impurity concentration in the carrier accumulation layer 5.

Compared to a position deeper than the peak position of the impurity concentration in the carrier accumulation layer 5 (a position closer to the lower surface of the semiconductor substrate), at a position shallower than the peak position of the impurity concentration in the carrier accumulation layer 5 (a position closer to the upper surface of the semiconductor substrate), a depletion layer is hard to extend to reduce an electric field. According to the seventh modification, it is possible to separate the boundary insulating film 8 involved in the reliability of the insulating film further from the peak position of the impurity concentration in the carrier accumulation layer 5 as a high electric field region, making it possible to improve the reliability of the insulating film.

While the seventh modification is applied to the semiconductor device shown in FIG. 3 in the exemplary case described above, the seventh modification may be applied to the semiconductor device shown in FIG. 1 or 2.

### <Eighth Modification>

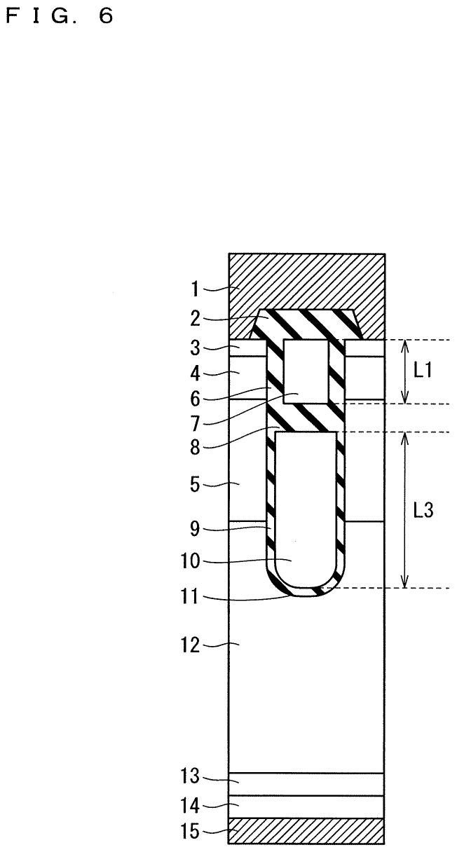

FIG. 6 is a sectional view of a semiconductor device according to an eighth modification of the first preferred embodiment. As shown in FIG. 6, a length L3 of the lower electrode 10 in the top-bottom direction may be larger than the length L1 of the upper electrode 7 in the top-bottom direction.

According to the eighth modification, by making the length L3 of the lower electrode 10 in the top-bottom direction having a side surface provided with the thin lower insulating film 9 effective against chip warpage larger than the length L1 of the upper electrode 7 in the top-bottom direction having a side surface provided with the thick upper insulating film 6, it becomes possible to enhance the effect of suppressing chip warpage.

While the eighth modification is applied to the semiconductor device shown in FIG. 3 in the exemplary case described above, the eighth modification may be applied to the semiconductor device shown in FIG. 1 or 2.

### <Ninth Modification>

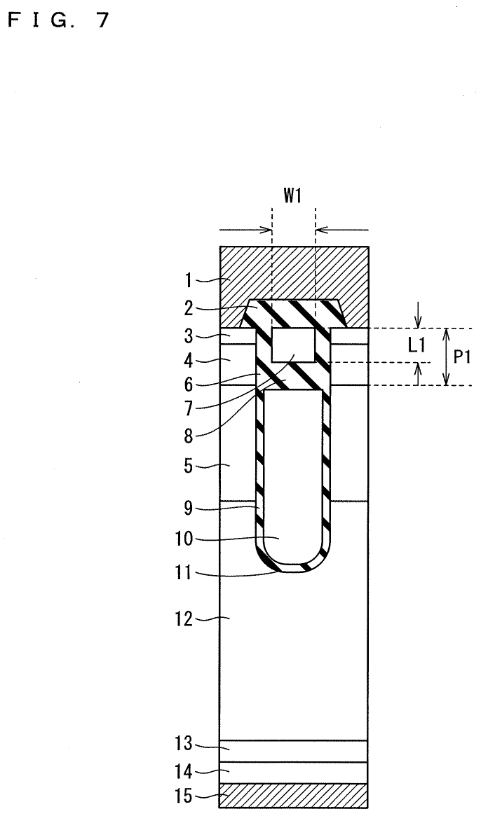

FIG. 7 is a sectional view of a semiconductor device according to a ninth modification of the first preferred embodiment. As shown in FIG. 7, the length L1 of the upper electrode 7 in the top-bottom direction may be shorter than the length P1 from the upper surface of the semiconductor substrate to a lower end of the base layer 4 in the top-bottom direction.

According to the ninth modification, by reducing the length L1 of the upper electrode 7 in the top-bottom direction, it becomes possible to reduce an aspect ratio of the length L1 of the upper electrode 7 in the top-bottom direction (the depth of the upper electrode 7) relative to the length W1 of the upper electrode 7 in the right-left direction (the width of the upper electrode 7) (L1/W1). Thus, it is possible to improve the embeddability of the upper electrode 7.

While the ninth modification is applied to the semiconductor device shown in FIG. 3 in the exemplary case described above, the ninth modification may be applied to the semiconductor device shown in FIG. 1 or 2.

### <Tenth Modification>

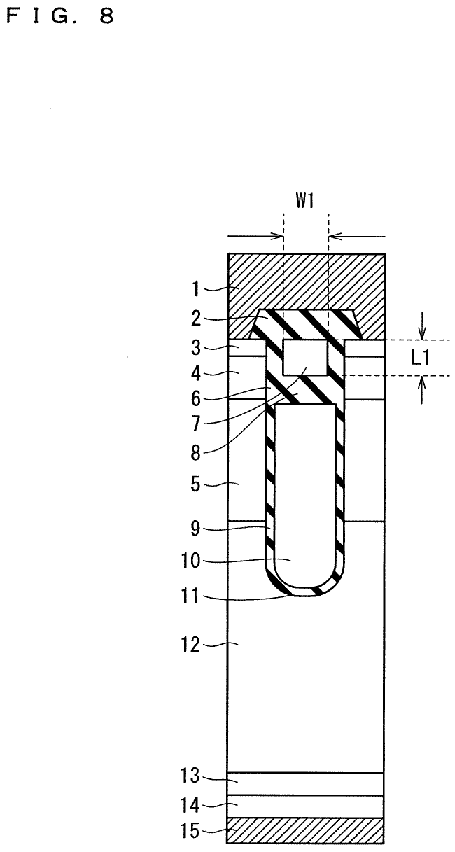

FIG. 8 is a sectional view of a semiconductor device according to a tenth modification of the first preferred embodiment. As shown in FIG. 8, the length L1 of the upper electrode 7 in the top-bottom direction may be shorter than the length W1 of the upper electrode 7 in the right-left direction.

According to the tenth modification, by reducing the length L1 of the upper electrode 7 in the top-bottom direction and increasing the length W1 of the upper electrode 7 in the right-left direction, it becomes possible to reduce an aspect ratio of the length L1 of the upper electrode 7 in the top-bottom direction (the depth of the upper electrode 7) relative to the length W1 of the upper electrode 7 in the right-left direction (the width of the upper electrode 7) (L1/W1). Thus, it is possible to improve the embeddability of the upper electrode 7.

While the tenth modification is applied to the semiconductor device shown in FIG. 3 in the exemplary case described above, the tenth modification may be applied to the semiconductor device shown in FIG. 1 or 2.

### <Eleventh Modification>

In the semiconductor devices shown in FIGS. 1 to 3, a material for the lower electrode 10 may be amorphous silicon.

According to the eleventh modification, by using amorphous silicon having less surface irregularities than polysilicon as a material for the lower electrode 10, it becomes possible to relax an electric field intensity between the upper electrode 7 and the lower electrode 10, making it possible to improve the reliability of the insulating film.

### <Twelfth Modification>

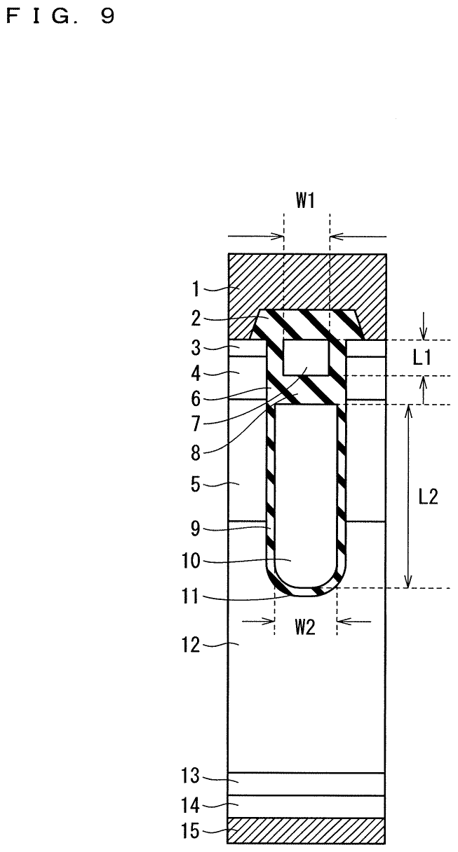

FIG. 9 is a sectional view of a semiconductor device according to a twelfth modification of the first preferred embodiment. As shown in FIG. 9, an aspect ratio of the length L1 of the upper electrode 7 in the top-bottom direction (the depth of the upper electrode 7) relative to the length W1 of the upper electrode 7 in the right-left direction (the width of the upper electrode 7) (L1/W1) may be set smaller than an aspect ratio of a length L2 of the lower electrode 10 in the top-bottom direction (the depth of the lower electrode 10) relative to a length W2 of the lower electrode 10 in the right-left direction (the width of the lower electrode 10) (L2/W2).

According to the twelfth modification, by making the aspect ratio of the upper electrode 7 (L1/W1) smaller than the aspect ratio of the lower electrode 10 (L2/W2), it becomes possible to improve the embeddability of the upper electrode 7.

While the twelfth modification is applied to the semiconductor device shown in FIG. 3 in the exemplary case described above, the twelfth modification may be applied to the semiconductor device shown in FIG. 1 or 2.

### <Thirteenth Modification>

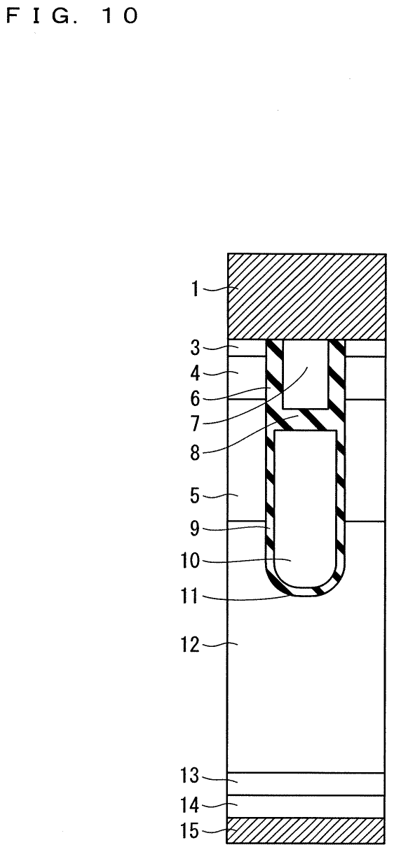

FIG. 10 is a sectional view of a semiconductor device according to a thirteenth modification of the first preferred embodiment. As shown in FIG. 10, the interlayer insulating film 2 may be omitted from a place over the upper electrode 7.

According to the thirteenth modification, by the absence of the interlayer insulating film 2 from a place over the upper electrode 7, it becomes possible for a current flowing in the upper electrode 7 to be emitted immediately into the emitter electrode 1. Specifically, voltage drop caused by the current flowing in the upper electrode 7 can become less influential to allow reduction in stress on the insulating film caused by the voltage drop. Thus, it is possible to improve the reliability of the insulating film.

While the thirteenth modification is applied to the semiconductor device shown in FIG. 3 in the exemplary case described above, the thirteenth modification may be applied to the semiconductor device shown in FIG. 1 or 2.

### <Fourteenth Modification>

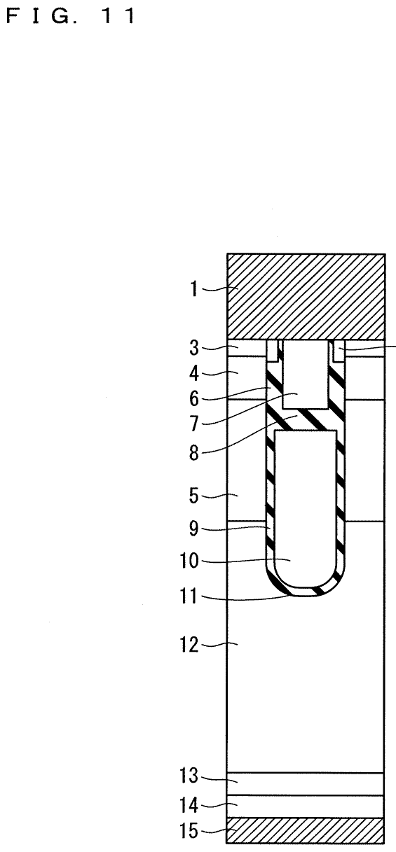

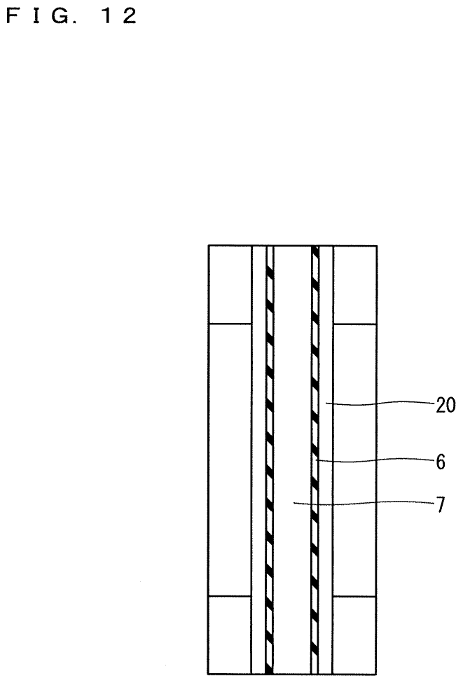

FIG. 11 is a sectional view of a semiconductor device according to a fourteenth modification of the first preferred embodiment. FIG. 12 is a plan view of the semiconductor device shown in FIG. 11 taken from the side of the upper surface. As shown in FIG. 11, the dummy active trench 11 has a side contact 20 having a side surface on one side in contact with the source layer 3 and the base layer 4.

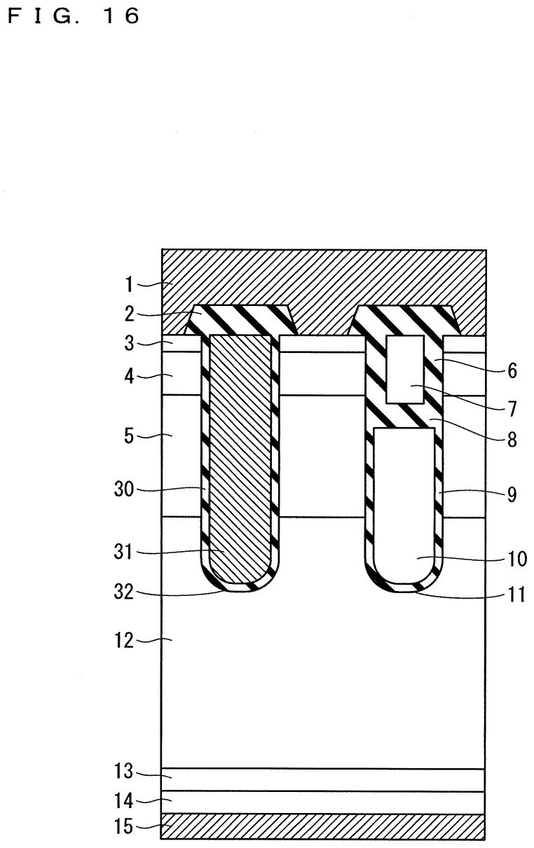

Employing this configuration allows the source layer 3 and the base layer 4 to be electrically connected to the emitter electrode 1 via the side contact 20. This allows reduction in a width from a next active trench (see FIG. 16 referred to later, for example) (a contact width of a mesa part), thereby realizing a finer size of a cell part. By making the cell part finer, it becomes possible to improve the characteristic of the semiconductor device such as on-voltage reduction.

While the fourteenth modification is applied to the semiconductor device shown in FIG. 3 in the exemplary case described above, the fourteenth modification may be applied to the semiconductor device shown in FIG. 1 or 2.

### <Fifteenth Modification>

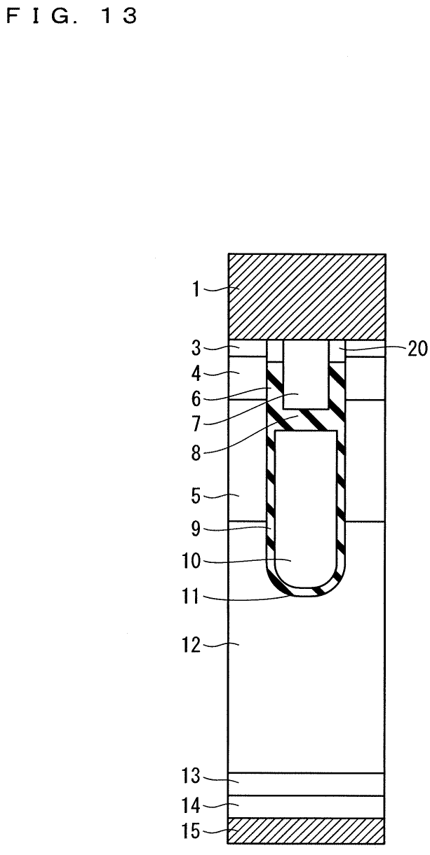

FIG. 13 is a sectional view of a semiconductor device according to a fifteenth modification of the first preferred embodiment. As shown in FIG. 13, the side contact 20 may have a side surface on one side in contact with the source layer 3 and the base layer 4, and a side surface on the other side in contact with the upper electrode 7.

In addition to the effect achieved by the fourteenth modification, employing this configuration allows the upper electrode 7 to be connected to the emitter electrode 1 further from a lateral side via the side contact 20. This increases a contact area of the upper electrode 7, making it possible to improve the stability of a potential with respect to the emitter electrode 1.

While the fifteenth modification is applied to the semiconductor device shown in FIG. 3 in the exemplary case described above, the fifteenth modification may be applied to the semiconductor device shown in FIG. 1 or 2.

### <Sixteenth Modification>

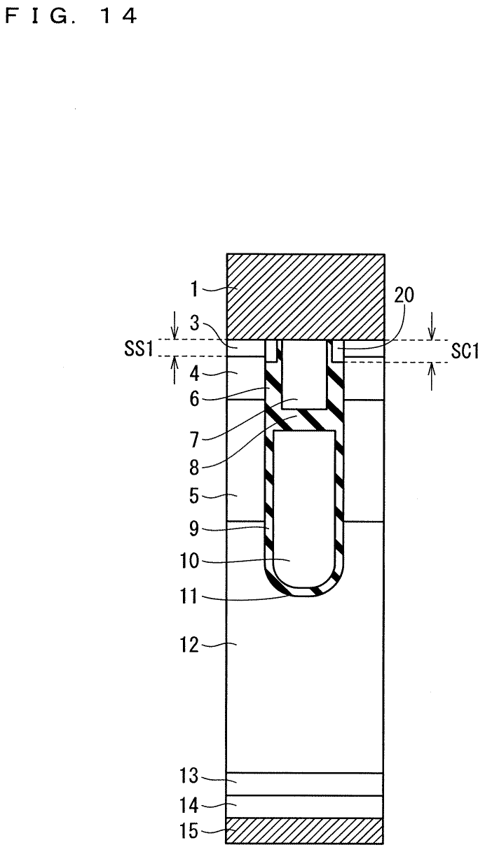

FIG. 14 is a sectional view of a semiconductor device according to a sixteenth modification of the first preferred embodiment. As shown in FIG. 14, a length SCI of the side contact 20 in the top-bottom direction (the depth of the side contact 20) may be larger than a length SS1 of the source layer 3 in the top-bottom direction (the depth of the source layer 3).

Employing this configuration allows increase in an area of contact of the side contact 20 with the source layer 3 and the base layer 4, thereby allowing reduction in a contact resistance.

While the sixteenth modification is applied to the semiconductor device shown in FIG. 3 in the exemplary case described above, the sixteenth modification may be applied to the semiconductor device shown in FIG. 1 or 2.

### <Seventeenth Modification>

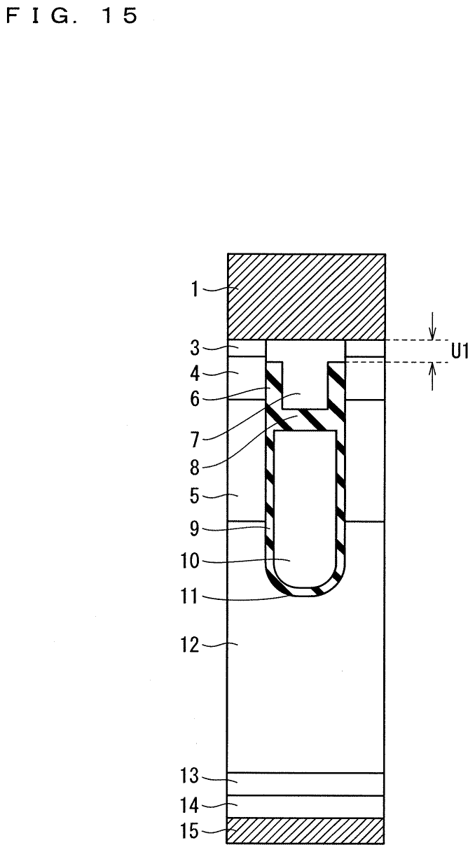

FIG. 15 is a sectional view of a semiconductor device according to a seventeenth modification of the first preferred embodiment. As shown in FIG. 15, an upper end of the upper insulating film 6 may be separated from the upper surface of the semiconductor substrate by a predetermined distance U1. In a sectional view, the upper electrode 7 has a T-shape.

Employing this configuration allows reduction in an effective aspect ratio of the upper electrode 7, making it possible to improve the embeddability of the upper electrode 7.

While the seventeenth modification is applied to the semiconductor device shown in FIG. 3 in the exemplary case described above, the seventeenth modification may be applied to the semiconductor device shown in FIG. 1 or 2.

### <Eighteenth Modification>

In the semiconductor devices shown in FIGS. 1 to 3, a material for the upper electrode 7 may be amorphous silicon.

According to the eighteenth modification, by using amorphous silicon having less surface irregularities than polysilicon as a material for the upper electrode 7, it becomes possible to relax an electric field intensity between the upper electrode 7 and the lower electrode 10, making it possible to improve the reliability of the insulating film.

### <Nineteenth Modification>

In the semiconductor devices shown in FIGS. 1 to 3, a material for the upper electrode 7 may be an insulator.

According to the nineteenth modification, by using an insulator as a material for the upper electrode 7, it becomes possible to relax an electric field intensity between the upper electrode 7 and the lower electrode 10, making it possible to improve the reliability of the insulating film.

### <Twentieth Modification>

In the semiconductor devices shown in FIGS. 1 to 3, a material for the upper electrode 7 may be metal.

According to the twentieth modification, using metal as a material for the upper electrode 7 allows reduction in a resistance in the upper electrode 7. This makes it possible for a current flowing in the upper electrode 7 to be emitted immediately into the emitter electrode 1. Specifically, voltage drop caused by the current flowing in the upper electrode 7 can become less influential to allow reduction in stress on the insulating film caused by the voltage drop. Thus, it is possible to improve the reliability of the insulating film.

### Second Preferred Embodiment

FIG. 16 is a sectional view of a semiconductor device according to a second preferred embodiment. The semiconductor device according to the second preferred embodiment characteristically includes a dummy active trench 11 and an active trench 32. The dummy active trench 11 is the same as the dummy active trench 11 shown in FIG. 3, so that the detailed description thereof is omitted here.

A semiconductor substrate is provided with the dummy active trench 11 and the active trench 32. The active trench 32 includes an active part 31 and an insulating film 30 formed in such a manner as to cover the active part 31 that are provided in a trench of the semiconductor substrate. The active part 31 is connected to a gate electrode.

In addition the effects achieved by the first preferred embodiment, according to the second preferred embodiment, it is possible to cause a current to flow in the semiconductor device by the provision of the active trench 32.

While the exemplary configuration in FIG. 16 includes the dummy active trench 11 shown in FIG. 3, this configuration may include the dummy active trench 11 shown in FIG. 1 or 2.

### <First Modification>

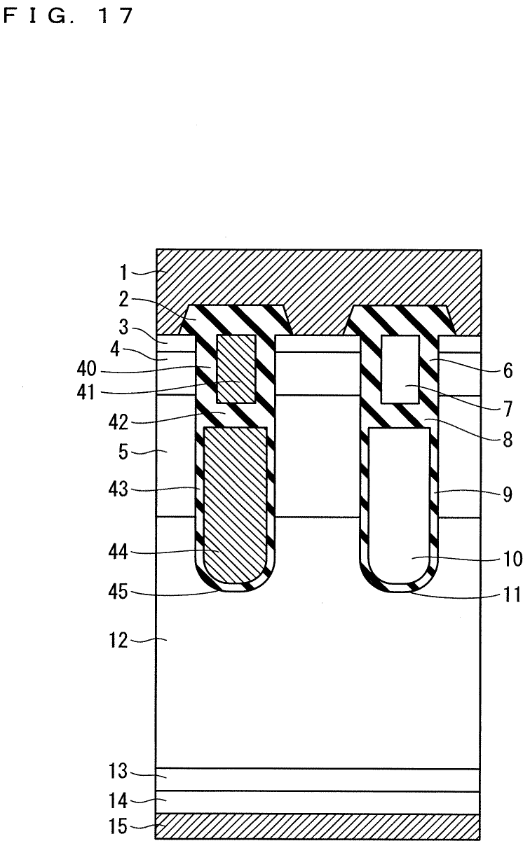

FIG. 17 is a sectional view of a semiconductor device according to a first modification of the second preferred embodiment. A dummy active trench 11 is the same as the dummy active trench 11 shown in FIG. 3, so that the detailed description thereof is omitted here.

As shown in FIG. 17, the semiconductor substrate is provided with the dummy active trench 11 and an active trench 45. The active trench 45 includes an upper active part 41 and a lower active part 44 provided in an upper part and a lower part respectively in a trench of the semiconductor substrate. The upper active part 41 and the lower active part 44 are connected to a gate electrode.

The active trench 45 includes an upper insulating film 40 formed on a side surface of the upper active part 41, a lower insulating film 43 formed on a side surface of the lower active part 44, and a boundary insulating film 42 formed between the upper active part 41 and the lower active part 44. The upper active part 41 and the lower active part 44 are electrically separated from each other via the boundary insulating film 42. The thickness of the upper insulating film 40 in the right-left direction is larger than the thickness of the lower insulating film 43 in the right-left direction.

According to the first modification, by providing the boundary insulating film 42 in the active trench 45, it becomes possible to reduce the area of an electrode electrically connected to the gate electrode by the area where the boundary insulating film 42 is formed, thereby allowing reduction in a gate capacitance.

While the exemplary configuration in FIG. 17 includes the dummy active trench 11 shown in FIG. 3, this configuration may include the dummy active trench 11 shown in FIG. 1. In this case, the position and size of the upper active part 41 may be the same as the position and size of the upper electrode 7 shown in FIG. 1.

### <Second Modification>

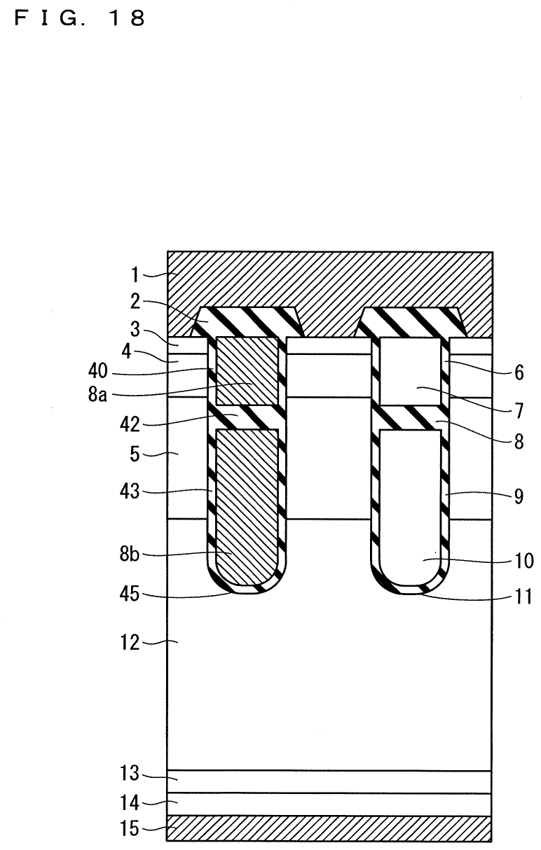

FIG. 18 is a sectional view of a semiconductor device according to a second modification of the second preferred embodiment. A dummy active trench 11 is the same as the dummy active trench 11 shown in FIG. 2, so that the detailed description thereof is omitted here.

As shown in FIG. 18, in the active trench 45, the thickness of the upper insulating film 40 in the right-left direction may be the same as the thickness of the lower insulating film 43 in the right-left direction. Alternatively, the thickness of the upper insulating film 40 in the right-left direction may be larger the thickness of the lower insulating film 43 in the right-left direction.

Employing this configuration allows reduction in a channel resistance, making it possible to reduce an ON voltage.

### <Third Modification>

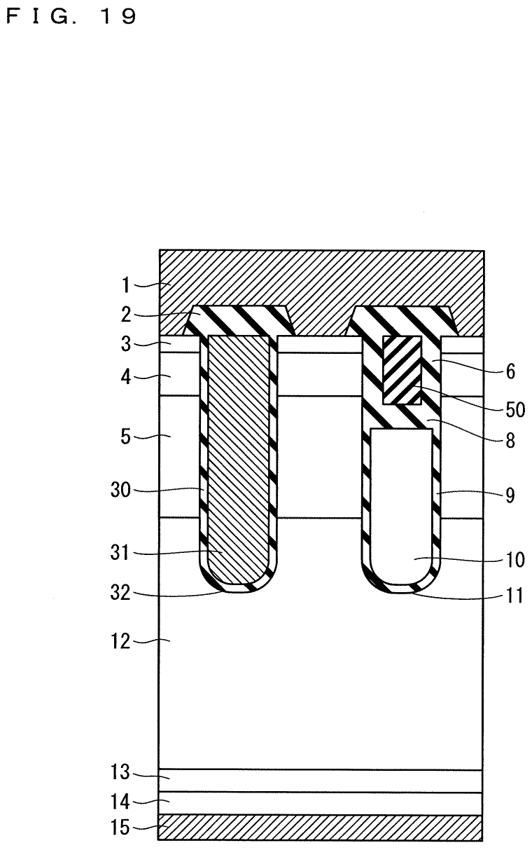

FIG. 19 is a sectional view of a semiconductor device according to a third modification of the second preferred embodiment. A dummy active trench 11 is the same as the dummy active trench 11 shown in FIG. 3 and an active trench 32 is the same as the active trench 32 shown in FIG. 16, so that the detailed descriptions thereof are omitted here.

As shown in FIG. 19, a material for the upper electrode 7 is an insulator 50, and the insulator 50 may be a chemical vapor deposition (CVD) film. In another case, an impurity concentration in the insulator 50 may be higher than an impurity concentration in the lower insulating film 9.

As the insulator 50 as a material for the upper electrode 7, using a CVD film prepared by the CVD process such as a film of high temperature oxide (HTO), tetra ethoxy silane (TEOS), or boron phospho silicate glass (BPSG) having a lower formation temperature than a thermal oxidation film allows a formation temperature of the insulating film to be lowered. This makes it possible to suppress thermal expansion to realize reduction in stress to be caused during formation of the insulating film. Generally, the CVD film has the characteristic of being higher in impurity concentration than the thermal oxidation film.

While the exemplary configuration in FIG. 19 includes the dummy active trench 11 shown in FIG. 3, this configuration may include the dummy active trench 11 shown in FIG. 1 or 2. While the exemplary configuration in FIG. 19 includes the active trench 32 shown in FIG. 16, this configuration may include the active trench 45 shown in FIG. 17 or 18.

### <Fourth Modification>

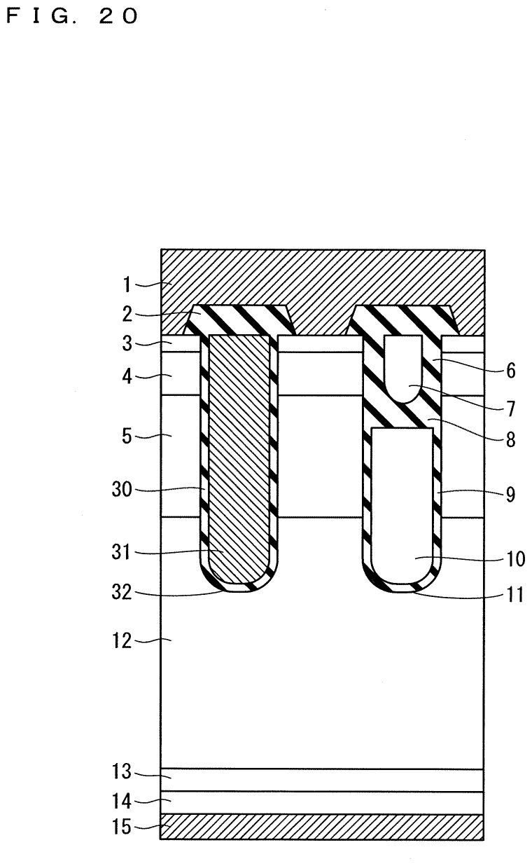

FIG. 20 is a sectional view of a semiconductor device according to a fourth modification of the second preferred embodiment. A dummy active trench 11 is the same as the dummy active trench 11 shown in FIG. 3 and an active trench 32 is the same as the active trench 32 shown in FIG. 16, so that the detailed descriptions thereof are omitted here.

As shown in FIG. 20, a corner at a lower end of the upper electrode 7 may have a curvature. Employing this configuration makes it possible to relax electric field concentration on the corner of the upper electrode 7.

While the exemplary configuration in FIG. 20 includes the dummy active trench 11 shown in FIG. 3, this configuration may include the dummy active trench 11 shown in FIG. 1 or 2. While the exemplary configuration in FIG. 20 includes the active trench 32 shown in FIG. 16, this configuration may include the active trench 45 shown in FIG. 17 or 18.

### <Fifth Modification>

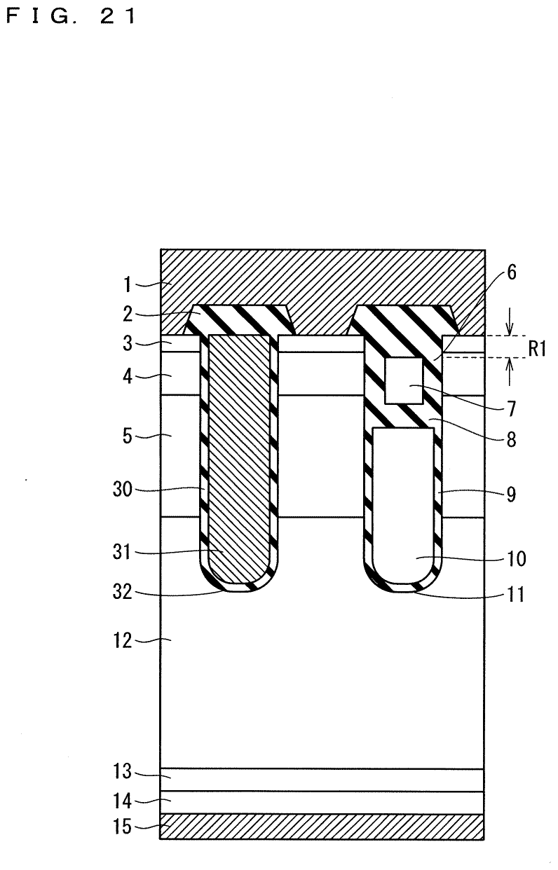

FIG. 21 is a sectional view of a semiconductor device according to a fifth modification of the second preferred embodiment. A dummy active trench 11 is the same as the dummy active trench 11 shown in FIG. 3 and an active trench 32 is the same as the active trench 32 shown in FIG. 16, so that the detailed descriptions thereof are omitted here.

As shown in FIG. 21, an upper end of the upper electrode 7 may be separated from the upper surface of the semiconductor substrate by a predetermined distance R1.

Employing this configuration reduces an aspect ratio of the upper electrode 7, making it possible to improve the embeddability of the upper electrode 7.

While the exemplary configuration in FIG. 21 includes the dummy active trench 11 shown in FIG. 3, this configuration may include the dummy active trench 11 shown in FIG. 1 or 2. While the exemplary configuration in FIG. 21 includes the active trench 32 shown in FIG. 16, this configuration may include the active trench 45 shown in FIG. 17 or 18.

### <Sixth Modification>

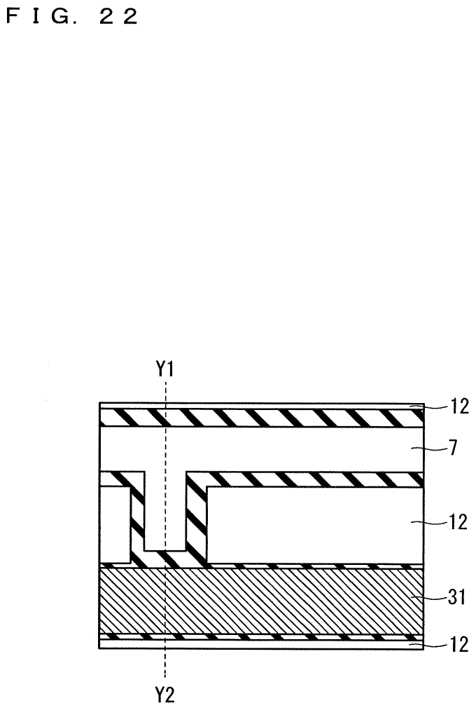

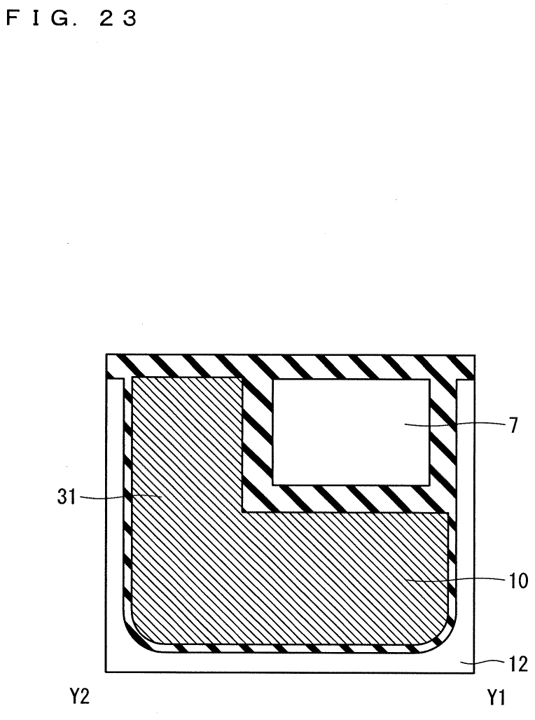

FIG. 22 is a plan view of a semiconductor device according to a sixth modification of the second preferred embodiment. FIG. 23 is a sectional view of the semiconductor device shown in FIG. 22 taken along Y1-Y2.

As shown in FIGS. 22 and 23, the dummy active trench 11 including the upper electrode 7 and the lower electrode 10 may be connected to the active trench 32 including the active part 31 via a trench. The dummy active trench 11 and the active trench 32 are partially connected to each other via the trench.

According to the sixth modification, by electrically connecting the dummy active trench 11 and the active trench 32 to each other, it becomes possible to stabilize electrical connection to a gate electrode.

### <Seventh Modification>

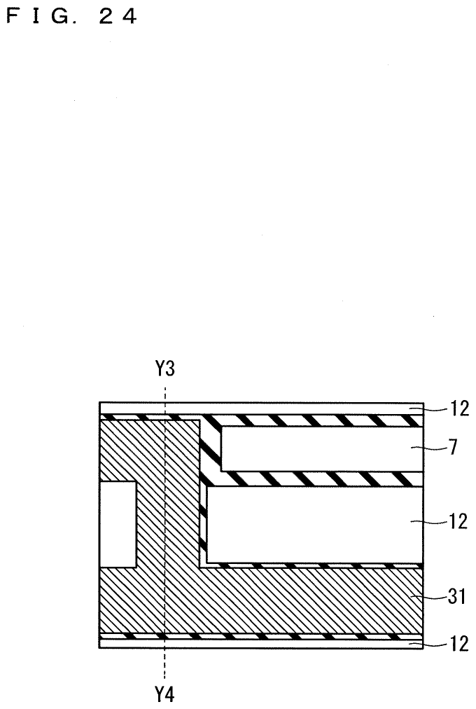

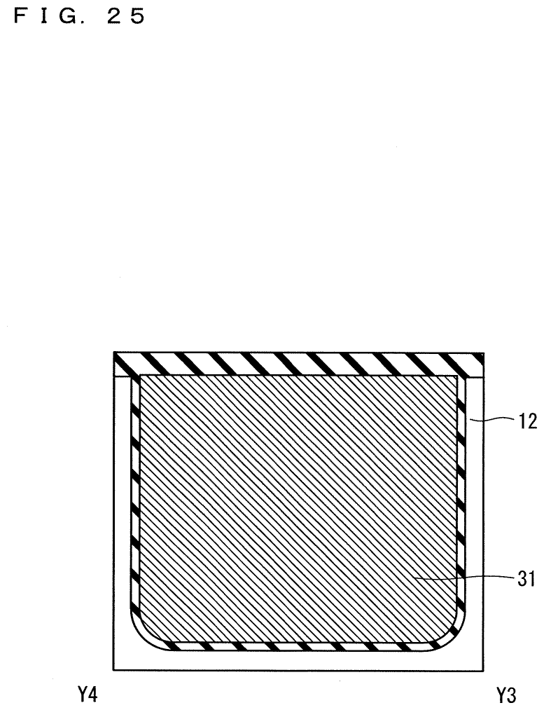

FIG. 24 is a plan view of a semiconductor device according to a seventh modification of the second preferred embodiment. FIG. 25 is a sectional view of the semiconductor device shown in FIG. 24 taken along Y3-Y4.

As shown in FIGS. 24 and 25, the dummy active trench 11 including the upper electrode 7 and the lower electrode 10 may be connected to the active trench 32 including the active part 31 via a trench. The active part 31 is provided in the trench forming the connection between the dummy active trench 11 and the active trench 32.

According to the seventh modification, by electrically connecting the dummy active trench 11 and the active trench 32 to each other, it becomes possible to stabilize electrical connection to a gate electrode. Furthermore, by providing the active part 31 in the trench forming the connection between the dummy active trench 11 and the active trench 32, an area of contact between the dummy active trench 11 and the active trench 32 is increased to allow the connection to be established at a reduced resistance.

### <Eighth Modification>

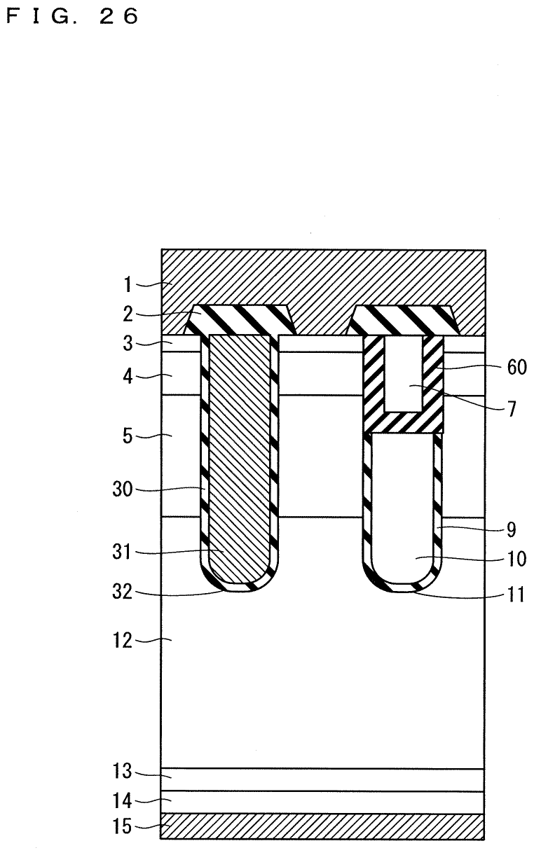

FIG. 26 is a sectional view of a semiconductor device according to an eighth modification of the second preferred embodiment. A dummy active trench 11 is the same as the dummy active trench 11 shown in FIG. 3 and an active trench 32 is the same as the active trench 32 shown in FIG. 16, so that the detailed descriptions thereof are omitted here.

As shown in FIG. 26, the upper insulating film 6 and the boundary insulating film 8 in the dummy active trench 11 may be CVD films 60.

The insulating film to be formed may either be a thermal oxidation film or a CVD film. Meanwhile, by forming a thermal oxidation film having excellent electrical stability as the lower insulating film 9 and forming CVD films such as films of HTO, TEOS, or BPSG having lower formation temperatures than the thermal oxidation film by the CVD process as the thick upper insulating film 6 and the thick boundary insulating film 8, it becomes possible to reduce the formation temperature of the insulating film. This realizes reduction in stress to be caused during formation of the insulating film. Generally, the CVD film has the characteristic of being higher in impurity concentration than the thermal oxidation film.

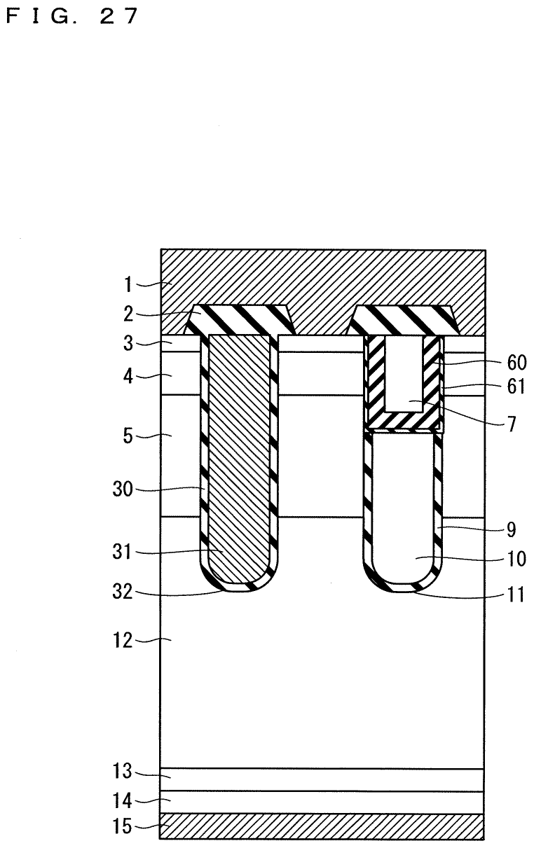

The thermal oxidation film having excellent electrical characteristics and the CVD film may be used in combination. More specifically, as shown in FIG. 27, a thermal oxidation film 61 may be formed in a first layer and the CVD film 60 may be formed in a second layer. By forming the thermal oxidation film 61 at a trench interference where excellent electrical characteristics are required, favorable gate characteristics are obtained. Furthermore, thermal stress can be reduced by the CVD film 60. In another case, stress occurring at the trench interface may be reduced by forming the CVD film 60 in the first layer corresponding to the trench interface to be subjected to the highest stress and by forming the thermal oxidation film 61 in the second layer.

While the upper insulating film 6 and the boundary insulating film 8 are formed as the CVD films 60 in the illustration in FIG. 26, at least one of the upper insulating film 6 and the boundary insulating film 8 may be formed as the CVD film 60. Furthermore, at least one of an impurity concentration in the upper insulating film 6 and an impurity concentration in the boundary insulating film 8 may be higher than an impurity concentration in the lower insulating film 9.

While the exemplary configuration in FIG. 26 includes the dummy active trench 11 shown in FIG. 3, this configuration may include the dummy active trench 11 shown in FIG. 1 or 2. While the exemplary configuration in FIG. 26 includes the active trench 32 shown in FIG. 16, this configuration may include the active trench 45 shown in FIG. 17 or 18.

The preferred embodiments of the present disclosure can be combined freely, and each preferred embodiment can be modified or omitted, as appropriate, within the range of the disclosure.

### <Appendixes>

The present disclosure described above will be summarized in Appendixes.

### (Appendix 1)

A semiconductor device comprising:
a semiconductor substrate;
an emitter electrode formed on the semiconductor substrate;
a gate electrode formed on the semiconductor substrate;
a drift layer of a first conductivity type formed in the semiconductor substrate;
a source layer of the first conductivity type formed in an upper surface side of the semiconductor substrate;
a base layer of a second conductivity type formed in the upper surface side of the semiconductor substrate;
a collector electrode formed under the semiconductor substrate; and
a dummy active trench including an upper electrode and a lower electrode provided in an upper part and a lower part respectively in a trench of the semiconductor substrate, the upper electrode being connected to the gate electrode or to the emitter electrode, or at a floating potential, the lower electrode being connected to the gate electrode or to the emitter electrode, or at a floating potential, wherein
the dummy active trench includes an upper insulating film formed on a side surface of the upper electrode, a lower insulating film formed on a side surface of the lower electrode, and a boundary insulating film formed between the upper electrode and the lower electrode,
the thickness of the upper insulating film in a right-left direction is larger than the thickness of the lower insulating film in the right-left direction, and
in a sectional view, the area of the upper electrode is smaller than the area of the lower electrode.

### (Appendix 2)

A semiconductor device comprising:
a semiconductor substrate;
an emitter electrode formed on the semiconductor substrate;
a gate electrode formed on the semiconductor substrate;
a drift layer of a first conductivity type formed in the semiconductor substrate;
a source layer of the first conductivity type formed in an upper surface side of the semiconductor substrate;
a base layer of a second conductivity type formed in the upper surface side of the semiconductor substrate;
a collector electrode formed under the semiconductor substrate; and
a dummy active trench including an upper electrode and a lower electrode provided in an upper part and a lower part respectively in a trench of the semiconductor substrate, the upper electrode being connected to the gate electrode or to the emitter electrode, or at a floating potential, the lower electrode being connected to the gate electrode or to the emitter electrode, or at a floating potential, wherein
the dummy active trench includes an upper insulating film formed on a side surface of the upper electrode, a lower insulating film formed on a side surface of the lower electrode, and a boundary insulating film formed between the upper electrode and the lower electrode,
the thickness of the boundary insulating film in a top-bottom direction is larger than the thickness of the lower insulating film in a right-left direction, and
in a sectional view, the area of the upper electrode is smaller than the area of the lower electrode.

### (Appendix 3)

The semiconductor device according to Appendix 1 or 2, wherein
the thickness of the upper insulating film in the right-left direction, the thickness of the boundary insulating film in a top-bottom direction, and the thickness of the lower insulating film in the right-left direction have a relationship as: the thickness of the boundary insulating film in the top-bottom direction>the thickness of the upper insulating film in the right-left direction>the thickness of the lower insulating film in the right-left direction.

### (Appendix 4)

The semiconductor device according to any one of Appendixes 1 to 3, wherein
the boundary insulating film is arranged above the center of the dummy active trench in a top-bottom direction.

### (Appendix 5)

The semiconductor device according to any one of Appendixes 1 to 4, wherein
a length from the upper surface of the semiconductor substrate to an upper end of the lower electrode is larger than the length from the upper surface of the semiconductor substrate to a lower end of the base layer.

### (Appendix 6)

The semiconductor device according to any one of Appendixes 1 to 5, further comprising:
a carrier accumulation layer of the first conductivity type provided between the base layer and the drift layer.

### (Appendix 7)

The semiconductor device according to Appendix 6, wherein
the boundary insulating film is arranged above a lower end of the carrier accumulation layer.

### (Appendix 8)

The semiconductor device according to Appendix 6, wherein
the boundary insulating film is arranged above the center of the carrier accumulation layer.

### (Appendix 9)

The semiconductor device according to Appendix 6, wherein
the boundary insulating film is arranged above a peak position of an impurity concentration in the carrier accumulation layer.

### (Appendix 10)

The semiconductor device according to any one of Appendixes 1 to 9, wherein
the length of the lower electrode in a top-bottom direction is larger than the length of the upper electrode in the top-bottom direction.

### (Appendix 11)

The semiconductor device according to any one of Appendixes 1 to 10, wherein
the length of the upper electrode in a top-bottom direction is shorter than the length from the upper surface of the semiconductor substrate to a lower end of the base layer.

### (Appendix 12)

The semiconductor device according to any one of Appendixes 1 to 11, wherein
the length of the upper electrode in a top-bottom direction is shorter than the length of the upper electrode in the right-left direction.

### (Appendix 13)

The semiconductor device according to any one of Appendixes 1 to 12, wherein
a material for the lower electrode is amorphous silicon.

### (Appendix 14)

The semiconductor device according to any one of Appendixes 1 to 13, wherein
an aspect ratio of the length of the upper electrode in a top-bottom direction relative to the length of the upper electrode in the right-left direction is smaller than an aspect ratio of the length of the lower electrode in the top-bottom direction relative to the length of the lower electrode in the right-left direction.

### (Appendix 15)

The semiconductor device according to any one of Appendixes 1 to 14, wherein
an interlayer insulating film is absent in a place over the upper electrode.

### (Appendix 16)

The semiconductor device according to any one of Appendixes 1 to 15, wherein
the dummy active trench further includes a side contact having a side surface on one side in contact with the source layer and the base layer.

### (Appendix 17)

The semiconductor device according to Appendix 16, wherein
the side contact has a side surface on the other side in contact with the upper electrode.

### (Appendix 18)

The semiconductor device according to Appendix 16, wherein
the length of the side contact in a top-bottom direction is larger than the length of the source layer in the top-bottom direction.

### (Appendix 19)

The semiconductor device according to any one of Appendixes 1 to 18, wherein
an upper end of the upper insulating film is separated from the upper surface of the semiconductor substrate by a predetermined distance.

### (Appendix 20)

The semiconductor device according to any one of Appendixes 1 to 19, wherein
a material for the upper electrode is amorphous silicon.

### (Appendix 21)

The semiconductor device according to any one of Appendixes 1 to 19, wherein
a material for the upper electrode is an insulator.

### (Appendix 22)

The semiconductor device according to any one of Appendixes 1 to 19, wherein
a material for the upper electrode is metal.

### (Appendix 23)

The semiconductor device according to any one of Appendixes 1 to 22, further comprising:
an active trench including an active part provided in a trench of the semiconductor substrate.

### (Appendix 24)

The semiconductor device according to Appendix 23, wherein
the active part is divided into an upper active part and a lower active part across a boundary insulating film.

### (Appendix 25)

The semiconductor device according to Appendix 21, wherein
the insulator is a chemical vapor deposition (CVD) film.

### (Appendix 26)

The semiconductor device according to Appendix 21, wherein
an impurity concentration in the insulator is higher than an impurity concentration in the lower insulating film.

### (Appendix 27)

The semiconductor device according to any one of Appendixes 1 to 26, wherein
a corner at a lower end of the upper electrode has a curvature.

### (Appendix 28)

The semiconductor device according to any one of Appendixes 1 to 27, wherein
an upper end of the upper electrode is separated from the upper surface of the semiconductor substrate by a predetermined distance.

### (Appendix 29)

The semiconductor device according to Appendix 23, wherein
the dummy active trench and the active trench are connected to each other via a trench.

### (Appendix 30)

The semiconductor device according to Appendix 29, wherein
the active part is formed in the trench.

### (Appendix 31)

The semiconductor device according to any one of Appendixes 1 to 30, wherein
at least one of the upper insulating film and the boundary insulating film is a chemical vapor deposition (CVD) film.

### (Appendix 32)

The semiconductor device according to any one of Appendixes 1 to 31, wherein
at least one of an impurity concentration in the upper insulating film and an impurity concentration in the boundary insulating film is higher than an impurity concentration in the lower insulating film.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
an emitter electrode formed on the semiconductor substrate;
a gate electrode formed on the semiconductor substrate;
a drift layer of a first conductivity type formed in the semiconductor substrate;
a source layer of the first conductivity type formed in an upper surface side of the semiconductor substrate;
a base layer of a second conductivity type formed in the upper surface side of the semiconductor substrate;
a collector electrode formed under the semiconductor substrate; and
a dummy active trench including an upper electrode and a lower electrode provided in an upper part and a lower part respectively in a trench of the semiconductor substrate, the upper electrode being connected to the gate electrode or to the emitter electrode, or at a floating potential, the lower electrode being connected to the gate electrode or to the emitter electrode, or at a floating potential, wherein
the dummy active trench includes an upper insulating film formed on a side surface of the upper electrode, a lower insulating film formed on a side surface of the lower electrode, and a boundary insulating film formed between the upper electrode and the lower electrode,
the thickness of the upper insulating film in a right-left direction is larger than the thickness of the lower insulating film in the right-left direction, and
in a sectional view, the area of the upper electrode is smaller than the area of the lower electrode.

2. A semiconductor device comprising:
a semiconductor substrate;
an emitter electrode formed on the semiconductor substrate;
a gate electrode formed on the semiconductor substrate;
a drift layer of a first conductivity type formed in the semiconductor substrate;
a source layer of the first conductivity type formed in an upper surface side of the semiconductor substrate;
a base layer of a second conductivity type formed in the upper surface side of the semiconductor substrate;
a collector electrode formed under the semiconductor substrate; and
a dummy active trench including an upper electrode and a lower electrode provided in an upper part and a lower part respectively in a trench of the semiconductor substrate, the upper electrode being connected to the gate electrode or to the emitter electrode, or at a floating potential, the lower electrode being connected to the gate electrode or to the emitter electrode, or at a floating potential, wherein
the dummy active trench includes an upper insulating film formed on a side surface of the upper electrode, a lower insulating film formed on a side surface of the lower electrode, and a boundary insulating film formed between the upper electrode and the lower electrode,
the thickness of the boundary insulating film in a top-bottom direction is larger than the thickness of the lower insulating film in a right-left direction, and
in a sectional view, the area of the upper electrode is smaller than the area of the lower electrode.

3. The semiconductor device according to claim 1, wherein
the thickness of the upper insulating film in the right-left direction, the thickness of the boundary insulating film in a top-bottom direction, and the thickness of the lower insulating film in the right-left direction have a relationship as: the thickness of the boundary insulating film in the top-bottom direction>the thickness of the upper insulating film in the right-left direction>the thickness of the lower insulating film in the right-left direction.

4. The semiconductor device according to claim 1, wherein
the boundary insulating film is arranged above the center of the dummy active trench in a top-bottom direction.

5. The semiconductor device according to claim 1, wherein
a length from the upper surface of the semiconductor substrate to an upper end of the lower electrode is larger than the length from the upper surface of the semiconductor substrate to a lower end of the base layer.

6. The semiconductor device according to claim 1, further comprising:
a carrier accumulation layer of the first conductivity type provided between the base layer and the drift layer.

7. The semiconductor device according to claim 6, wherein
the boundary insulating film is arranged above a lower end of the carrier accumulation layer.

8. The semiconductor device according to claim 6, wherein
the boundary insulating film is arranged above the center of the carrier accumulation layer.

9. The semiconductor device according to claim 6, wherein
the boundary insulating film is arranged above a peak position of an impurity concentration in the carrier accumulation layer.

10. The semiconductor device according to claim 1, wherein
the length of the lower electrode in a top-bottom direction is larger than the length of the upper electrode in the top-bottom direction.

11. The semiconductor device according to claim 1, wherein
the length of the upper electrode in a top-bottom direction is shorter than the length from the upper surface of the semiconductor substrate to a lower end of the base layer.

12. The semiconductor device according to claim 1, wherein
the length of the upper electrode in a top-bottom direction is shorter than the length of the upper electrode in the right-left direction.

13. The semiconductor device according to claim 1, wherein
a material for the lower electrode is amorphous silicon.

14. The semiconductor device according to claim 1, wherein
an aspect ratio of the length of the upper electrode in a top-bottom direction relative to the length of the upper electrode in the right-left direction is smaller than an aspect ratio of the length of the lower electrode in the top-bottom direction relative to the length of the lower electrode in the right-left direction.

15. The semiconductor device according to claim 1, wherein
an interlayer insulating film is absent in a place over the upper electrode.

16. The semiconductor device according to claim 1, wherein
the dummy active trench further includes a side contact having a side surface on one side in contact with the source layer and the base layer.

17. The semiconductor device according to claim 16, wherein
the side contact has a side surface on the other side in contact with the upper electrode.

18. The semiconductor device according to claim 16, wherein
the length of the side contact in a top-bottom direction is larger than the length of the source layer in the top-bottom direction.

19. The semiconductor device according to claim 1, wherein
an upper end of the upper insulating film is separated from the upper surface of the semiconductor substrate by a predetermined distance.

20. The semiconductor device according to claim 1, wherein
a material for the upper electrode is amorphous silicon.

21. The semiconductor device according to claim 1, wherein
a material for the upper electrode is an insulator.

22. The semiconductor device according to claim 1, wherein
a material for the upper electrode is metal.

23. The semiconductor device according to claim 1, further comprising:
an active trench including an active part provided in a trench of the semiconductor substrate.

24. The semiconductor device according to claim 23, wherein
the active part is divided into an upper active part and a lower active part across a boundary insulating film.

25. The semiconductor device according to claim 21, wherein
the insulator is a chemical vapor deposition (CVD) film.

26. The semiconductor device according to claim 21, wherein
an impurity concentration in the insulator is higher than an impurity concentration in the lower insulating film.

27. The semiconductor device according to claim 1, wherein
a corner at a lower end of the upper electrode has a curvature.

28. The semiconductor device according to claim 1, wherein
an upper end of the upper electrode is separated from the upper surface of the semiconductor substrate by a predetermined distance.

29. The semiconductor device according to claim 23, wherein
the dummy active trench and the active trench are connected to each other via a trench.

30. The semiconductor device according to claim 29, wherein
the active part is formed in the trench.

31. The semiconductor device according to claim 1, wherein
at least one of the upper insulating film and the boundary insulating film is a chemical vapor deposition (CVD) film.

32. The semiconductor device according to claim 1, wherein
at least one of an impurity concentration in the upper insulating film and an impurity concentration in the boundary insulating film is higher than an impurity concentration in the lower insulating film.
